(19) United States
(12) Patent Application Publication
(10) Pub. No.: US 2020/0022264 A1
(43) Pub. Date: Jan. 16, 2020

(54) ULTRA-THIN, REMOVABLE, CATALYTIC FILM FOR LASER DIRECT STRUCTURING (LDS) ON A BLACK OR OPAQUE SUBSTRATE AND THE PROCESS THEREBY

(71) Applicant: SABIC GLOBAL TECHNOLOGIES B.V., Bergen op Zoom (NL)

(72) Inventors: Yunan CHENG, Shanghai (CN); Liang SHEN, Shanghai (CN)

(21) Appl. No.: 16/490,130

(22) PCT Filed: Mar. 2, 2018
(86) PCT No.: PCT/IB2018/051352

§ 371 Date: Aug. 30, 2019

Related U.S. Application Data
(60) Provisional application No. 62/466,015, filed on Mar. 2, 2017.

(51) Int. Cl. H05K 3/18; B29C 35/08; B29C 48/08; B29C 48/00; B29C 65/02; C23C 18/16; C23C 18/20

(52) U.S. Cl. CPC H05K 3/185; B29C 35/0805; B29C 48/08; B29C 48/022; B29C 65/02; B29K 2069/00; C23C 18/204; H05K 2203/107; H05K 2203/0706; H05K 2203/072; B29C 2035/0838; C23C 18/1641

(57) ABSTRACT

A process of forming an article utilizes an ultra-thin, removable, catalytic film for Laser Direct Structuring (LDS). The process includes forming a film from a laser-activatable material, the film exhibiting thickness of less than 100 μm; applying the film to a black or opaque substrate to form a film-substrate element; applying a laser to the film-substrate element; removing a portion of the film from the film-substrate element; and applying metal plating to a portion of the black or opaque substrate. Removal of the film from the film-substrate element may follow metal plating of the black or opaque substrate. An article formed by the process may be useful in a computer device, electromagnetic interference device, printed circuit, Wi-Fi device, Bluetooth device, GPS device, cellular antenna device, smart phone device, automotive device, medical device, sensor device, RF antenna device, LED device, RFID device, or a component of a cell phone antenna.

### TECHNICAL FIELD

The disclosure concerns laser-plateable thermoplastic laser direct structuring compositions, process, and articles made therefrom.

### BACKGROUND

Laser direct structuring (LDS), which may be implemented as a Molded Interconnect Device (MID) technology, can produce conductive path structures on non-conductive plastic surfaces. LDS has been widely used in electronic application areas such as antennas and circuits. Compared to conventional methods for making such electronic components, including hot stamping and two-shot injection molding, LDS provides advantages in design capability, cycle time, cost efficiency, miniaturization, diversification, and functionality. As a result, LDS has been widely adopted in the electronics industry.

To make the thermoplastics with LDS capability, a laser activatable agent is provided to release metal “seeds” after laser treatment. Presently, only a limited number of metal compounds are suitable for LDS application, including copper hydroxide phosphate and copper chromite black. Copper hydroxide phosphate provides good plating efficiency but weak thermal stability, particularly in high heat application areas. Copper chromite black offers good thermal stability but can only be used to make black color products due to its intrinsic dark color.

These and other shortcomings of the art are addressed by aspects of the present disclosure.

### SUMMARY

It is desirable to maintain laser processing since laser etching produces usable metal-plastic bonding strength. However, it is also desirable to change the location of the laser-responsive material from incorporation into the bulk of the substrate composition to placement at the surface of the substrate so that the corresponding substrate performance and cost will not be altered.

The present disclosure relates to a processing concept including forming LDS pellets into an ultra-thin, laser-responsive film; applying the film with or to a black or opaque substrate to form a film-substrate element; applying a laser to the film-substrate element; removing at least a portion of the film from the black or opaque substrate, and metallizing the black or opaque substrate.

In the present disclosure, an ultra-thin film containing laser-responsive catalyst is presented to enable LDS or similar activation process for subsequent metal plating on the black or opaque substrate, which do not necessarily contain an LDS additive. Such film may be further removed after a LDS or plating procedure. Therefore the cost, mechanical properties, color, opacity, shape and any other properties of the substrate may be maintained.

In certain aspects, a method may comprise: (a) forming a film from a laser-activatable material, the film having a thickness of less than 100 μm; (b) applying the film to a black or opaque substrate to form a film-substrate element; (c) applying a laser to the film-substrate element; (d) removing at least a portion of the film from the film-substrate element; and (e) applying a metal plating to at least a portion of the black or opaque substrate, wherein step (d) may be performed prior to or after step (e).

In further aspects, a method of forming an article may comprise: (a) forming a film from a laser-activatable material, the film having a thickness of less than 100 μm; (b) applying the film to a black or opaque substrate to form a film-substrate element; (c) applying a laser to the film-substrate element; (d) removing at least a portion of the film from the film-substrate element; and (e) applying a metal plating to at least a portion of the black or opaque substrate, wherein step (d) may be performed prior to or after step (e).

### BRIEF DESCRIPTION OF THE FIGURES

FIG. 1 presents a method of utilizing an ultra-thin, laser responsive film in conjunction with laser processing and metal plating to form an article from a black or opaque substrate according to an aspect of the disclosure.

FIG. 2 presents a cross section of an activated ultra-thin, laser responsive film portion of a film-substrate element during laser processing according to an aspect of the disclosure.

FIG. 3 presents a cross section of an activated ultra-thin, laser responsive film portion and an activated black or opaque substrate portion during laser processing according to an aspect of the disclosure.

FIG. 4 presents a method of utilizing an ultra-thin, laser responsive film in conjunction with laser processing and metal plating to form an article from a black or opaque substrate according to an aspect of the disclosure.

### DETAILED DESCRIPTION

The present disclosure relates to a method for forming a laser-responsive article capable of metal plating and articles made therefrom a removable ultra-thin film containing a laser responsive catalyst for facilitating LDS on black or opaque substrates.

In further aspects, the method of forming a laser-responsive article capable of metal plating includes forming a film from a laser-activatable material; applying the film to a black or opaque substrate to form a film-substrate element; applying a laser to the film-substrate element; removing at least a portion of the film from the film-substrate element; and applying a metal plating to at least a portion of the black or opaque substrate. The step of removing at least a portion of the film from the film-substrate element may be performed before or after the step of applying a metal plating to at least a portion of the black or opaque substrate. In certain aspects the film has a thickness of less than 100 μm.

Given the preferred use of laser processing due to the usable metal-plastic bonding strength produced from laser etching, the present disclosure addresses the problem of thermoplastic compositions with limitations related to thermal stability and dark color in appearance. Specifically, few metal compounds are suitable for LDS application. Examples of such compounds include copper hydroxide phosphate and copper chromite black. Copper hydroxide phosphate exhibits good plating efficiency, but poor thermal stability, particularly in high heat application areas. Copper chromite black exhibits good thermal stability, but end-use products are limited to a black color due to the intrinsic dark appearance of the compound. The present disclosure relates to processes that utilize ultra-thin, laser responsive film utilized to facilitate LDS on plateable black or opaque substrate compounds with light color and good thermal stability.

### Surface LDS Processing

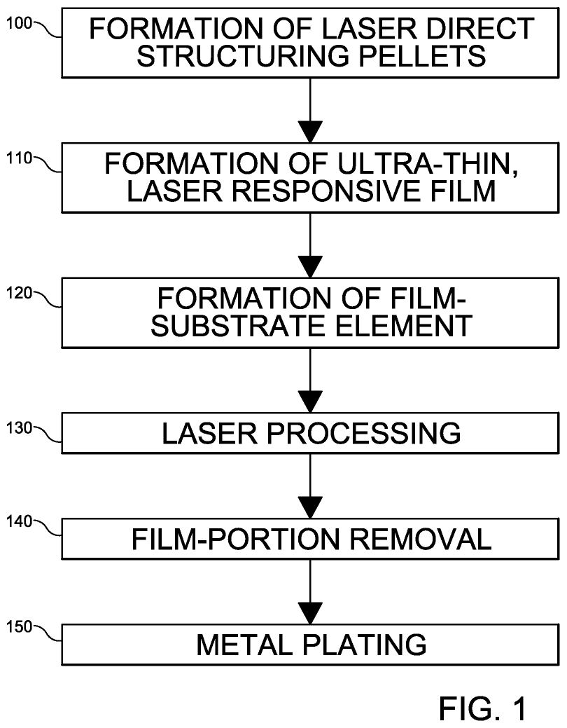

Referring now to FIG. 1, the methods of the present disclosure and articles made therefrom include the formation of laser direct structuring (LDS) pellets in step 100. LDS pellets remain separate and are selected to form an ultra-thin, laser responsive film in step 110. The ultra-thin, laser responsive film formed from LDS pellets comprises a laser responsive catalyst to be used in a laser processing technique, such as LDS. After formation of the ultra-thin, laser responsive film, the film is applied to a black or opaque substrate in step 120 to form a film-substrate element. A laser is applied to the film-substrate element at step 130, which forms an etched film-substrate element. Upon completion of step 130, at least part of the film layer is removed from the etched film-substrate element in step 140. Following step 140, a metal plating step is performed on at least a portion of the black or opaque substrate in step 150.

### Laser Direct Structuring Pellets

In a conventional laser direct structuring (LDS) process, an LDS additive is incorporated as a component of a thermoplastic resin. Upon commencement of the LDS process, a laser beam exposes the LDS additive to place it at the surface of the thermoplastic resin and to activate metal atoms from the LDS additive.

As described above, methods of the present disclosure and articles made therefrom include forming a laser activatable material at step 100. In particular aspects, the laser activatable material is in the form of thermoplastic resin-based laser direct structuring (LDS) pellets. Following a similar principle behind the use of an LDS additive, thermoplastic resin-based LDS pellets are selected to enable a thermoplastic composition to be used in a laser direct structuring process.

In some aspects, LDS pellets used in the present disclosure contain a core/shell structured LDS additive where a core is coated with a laser activatable, or responsive component. The ‘laser activatable component’ is a component that releases metal seeds after laser activating. The metal seeds act as catalysts for chemical plating. In certain aspects of the disclosure in which the LDS pellets include a core-shell structured LDS additive, the LDS additive may comprise from about 0.1 wt % to about 90 wt % of the LDS pellet, with the balance being thermoplastic resin. In further aspects, the LDS additive may comprise from about 1 wt % to about 20 wt %, or from about 1 wt % to about 10 wt % of the LDS pellet, with the balance being thermoplastic resin. In various aspects, the thermoplastic resin may be included in the core of the LDS pellet, in the shell of the LDS pellet, or in both the core and the shell of the LDS pellet. In still further aspects, an LDS pellet having a core-shell structured LDS additive does not include a thermoplastic resin.

In certain aspects in which an LDS pellet having a core-shell structured LDS additive is used, the core comprises a filler, such as but not limited to an inorganic filler, and the shell comprises a laser activatable component. In addition, thermoplastic resin may be included in one or more of the core and shell as described above. In particular aspects, the laser activatable component includes one or more of copper and tin.

In some aspects, the core comprises TiO₂, mica or talc. In certain aspects, the laser activatable component includes one or more of tin and antimony. In particular aspects the laser activatable component is a mixed metal oxide comprising tin oxide and antimony. In some aspects the LDS pellet comprises about 10 wt % to about 80 wt % core including the filler (and thermoplastic resin if included) and about 20 wt % to about 90 wt % shell including the laser activatable component (and thermoplastic resin if included). In certain aspects the LDS pellet comprises about 30 wt % to about 70 wt % core including the filler (and thermoplastic resin if included) and about 30 wt % to about 70 wt % shell including the laser activatable component (and thermoplastic resin if included), or about 45 wt % to about 65 wt % core including the filler (and thermoplastic resin if included) and about 35 wt % to about 55 wt % shell including the laser activatable component (and thermoplastic resin if included). Exemplary laser activatable components for inclusion in the shell include, but are not limited to, Tin-Antimony Cassiterite Grey [(Sb/Sn)O2], copper hydroxide phosphate and combinations thereof.

In certain aspects, the core is essentially completely covered with the shell component. LDS pellets may come in various shapes and sizes. Some pellets are shaped as flakes, platelets, fibers, needles or spheres. In certain aspects, the size or shape may impact plating or thermoplastic composition properties, such as thermal conductivity values. In some aspects, a flake or platelet shape may be preferred.

As described above, the present disclosure departs from the typical LDS process by separating the LDS pellets from the bulk thermoplastic resin that forms the eventual black or opaque substrate. Conventional LDS processing incorporates laser activatable material as an additive to the bulk thermoplastic composition.

In an aspect, LDS pellets are formed and include an initial drying period of approximately 4-6 hours at a temperature of about 120° C.

The LDS pellets according to aspects of the disclosure include any suitable thermoplastic resin. In some aspects, the thermoplastic resin includes, but is not limited to polypropylene, polyethylene, ethylene based copolymer, polycarbonate (PC), polyamide, polyester, polyoxymethylene (POM), polybutylene terephthalate (PBT), polyethylene terephthalate (PET), polycyclohexylendimethylene terephthalate (PCT), liquid crystal polymers (LPC), polyphenylene sulfide (PPS), polyphenylene ether (PPE), polyphenylene oxide-polystyrene blends, polystyrene, high impact modified polystyrene, acrylonitrile-butadiene-styrene (ABS) terpolymer, acrylic polymer, polyetherimide (PEI), polyurethane, polyetheretherketone (PEEK), poly ether sulphone (PES), polyphthalamide (PPA) or mixtures thereof. In a particular aspect, the LDS pellets include a polycarbonate (PC) resin.

While aspects of the present disclosure describe the laser activatable material as being provided in the form of LDS pellets having a core and shell construction, it need not have such a construction and need not even be in pellet form. Rather, the laser activatable material can be in any conventional form suitable for the selected thermoplastic resin (if used), filler and laser activatable components. Suitable forms for the laser-activatable material include, but are not limited to, homogeneous pellets, blocks, powders and liquids. If such forms are used, the relative amounts of the filler, the laser activatable component and the thermoplastic resin (if used) may be consistent with those described above for the LDS pellet having a core and shell construction. For example, the laser activatable material (in whatever form used) may in some aspects include from about 0.1 wt % to about 90 wt % LDS additive, with the balance being thermoplastic resin, or in particular aspects from about 1 wt % to about 20 wt % LDS additive, with the balance being thermoplastic resin, or from about 1 wt % to about 10 wt % LDS additive, with the balance being thermoplastic resin. Further, in some aspects the LDS additive may include about 10 wt % to about 90 wt % filler relative to about 20 wt % to about 90 wt % laser activatable component, or in particular aspects the LDS additive may include about 30 wt % to about 70 wt % filler relative to about 30 wt % to about 70 wt % laser activatable component, or the LDS additive may include about 45 wt % to about 65 wt % filler relative to about 35 wt % to about 55 wt % laser activatable component.

### Ultra-Thin Laser-Responsive Film

The method of forming a laser-responsive article capable of metal plating according to aspects of the disclosure includes forming a film from the laser-activatable material formed at step 110. In certain aspects, the film has a thickness of less than 20 μm. In an aspect, the ultra-thin film is extruded from LDS pellets and comprises a laser activatable, or responsive catalyst to be used in a laser structuring process, such as LDS. As such, the ultra-thin, laser responsive film is selected such that, upon exposure to a laser beam, metal atoms are activated and exposed, and in areas not exposed by the laser beam, no metal atoms are exposed. In addition, the ultra-thin, laser responsive film is selected such that, after being exposed to laser beam, the etching area is capable of being plated to form conductive structure, or a track. Upon formation of such a conductive track, standard electro-less metal plating may occur.

Fabrication of the ultra-thin, laser responsive film may in some aspects occur through film extrusion. Following the drying period, LDS pellets are extruded at a suitable temperature (e.g., about 280° C.) to form an ultra-thin, laser responsive film that may be transparent, translucent, or both.

More specifically, in an aspect, the LDS pellets are dried at about 120° C. for about 4-6 hours and the film is extruded at about 280° C. to achieve a transparent or translucent film with a film thickness of less than about 100 μm. In certain aspects, the film thickness may be from about 1 μm to about 100 μm, from about 1 μm to about 50 μm, from about 1 μm to about 20 μm, or from about 5 μm to about 15 μm.

In an aspect, the fabricated ultra-thin, laser responsive film is present in an amount sufficient to enable plating of the track formed after activation by the laser while not adversely affecting mechanical properties. In an aspect, the ultra-thin laser responsive film thickness is smaller than a laser penetrating thickness so that the laser may penetrate beyond the film to an underlying thermoplastic black or opaque substrate, and activate both the film and the black or opaque substrate. In an aspect, the thickness of the ultra-thin, laser responsive film may be from about 5 μm to about 15 μm.

In a further aspect, as an example, the ultra-thin, removable, catalytic film enables the formation of electronic patterns on black or opaque substrates with complex features such as flexible, diverse shaping, etc., which may not be achieved using traditional LDS technology.

### Thermoplastic Black or Opaque Substrate Compositions

In various aspects, the articles formed according to the methods described herein may be formed of a bulk thermoplastic resin that forms the eventual black or opaque substrate.

In further aspects, the articles formed according to the methods described herein comprise an additive selected from coupling agents, antioxidants, mold release agents, UV absorbers, light stabilizers, heat stabilizers, impact modifiers, flow promoters, lubricants, plasticizers, pigments, dyes, anti-static agents, nucleating agents, anti-drip agents, acid scavengers, and combinations of two or more of the foregoing. In a further aspect, methods of the present disclosure and the articles made therefrom further comprise at least one additive selected from a flame retardant, a primary anti-oxidant, and a secondary anti-oxidant. In a still further aspect, single shot injection molding can be used to produce the parts or articles to be laser structured.

In one aspect, articles formed according to the methods described herein comprise at least one polymer component present in an amount from about 10 wt % to about 90 wt %. In various aspects, suitable polymer components may include, but are not limited to polypropylene, polyethylene, ethylene based copolymer, polycarbonate (PC), polyamide, polyester, polyoxymethylene (POM), polybutylene terephthalate (PBT), polyethylene terephthalate (PET), polycyclohexylendimethylene terephthalate (PCT), liquid crystal polymers (LPC), polyphenylene sulfide (PPS), polyphenylene ether (PPE), polyphenylene oxide-polystyrene blends, polystyrene, high impact modified polystyrene, acrylonitrile-butadiene-styrene (ABS) terpolymer, acrylic polymer, polyetherimide (PEI), polyurethane, polyetheretherketone (PEEK), poly ether sulphone (PES), polyphthalamide (PPA) or mixtures thereof. In a further aspect, the polymer component comprises a polypropylene, a polyethylene, an ethylene-based copolymer, a polycarbonate, a polyamide, a polyester, a polyoxymethylene (“POM”), a liquid crystal polymer (“LCP”), a polyphenylene sulfide (“PPS”), a polyphenylene ether (“PPE”), a polystyrene, a acrylonitrile-butadiene-styrene terpolymer (“ABS”), an acrylic polymer, a polyetherimide (“PEI”), a polyurethane, a polyethersulphone (“PES”), or a polyetheretherketone (“PEEK”), or combinations thereof.

Some preferred embodiments utilized polypropylene or poly(p-phenylene oxide) polymer. In some embodiments, the polypropylene can be a homopolymer and/or a copolymer. A homopolymer essentially comprises propylene monomers. In certain embodiments, the polypropylene copolymer comprises propylene monomers copolymerized with ethylene. The copolymer may be a random copolymer or a block copolymer.

Polymers such as polycarbonate, polypropylene, polyethylene, ethylene based copolymer, polycarbonate, polyamide, polyester, polyoxymethylene, liquid crystal, polyphenylene sulfide, polyphenylene ether, polyphenylene oxide-polystyrene blend, polystyrene, high impact modified polystyrene, acrylonitrile-butadiene-styrene, terpolymer, acrylic polymer, polyetherimide, polyurethane, polyetheretherketone, polyether sulfone, and thermoset polymer, or combinations thereof, generally known to a skilled artisan and are within the scope of the present disclosure. The above thermoplastic polymers are either commercially available or can be readily synthesized by synthetic methods well known to those of skill in the art.

The substrate composition may include exemplary components such as, but not limited to, copper chromite black, which may impart the black color or opaque appearance to the substrate.

Upon determination of a final black or opaque substrate composition, the ultra-thin, laser responsive film is compressed with the thermoplastic black or opaque substrate composition.

### Film-Substrate Element

Aspects of the method for forming a laser-responsive article capable of metal plating further include, at step 120, applying the ultra-thin, laser-responsive film to a thermoplastic black or opaque substrate to form a film-substrate element, at step 110.

In certain aspects, the present disclosure relates to film pressing technology. In an aspect, substrate-film affinity and removable implementations may be balanced. For example, the attachment between the black or opaque substrate and the film should be durable enough to facilitate laser processing but is in some aspects reversible to recover the appearance of substrate. In the present disclosure, methods for applying the film to the black or opaque substrate include, but are not limited to, hot stamping and/or electrostatic absorption.

In an aspect, upon selection of a desired shape and size of the thermoplastic substrate and eventual article, the ultra-thin, laser responsive film is formed to match the substrate shape and size. Such shape matching may be achieved through hot stamping of the ultra-thin, laser responsive film and the thermoplastic substrate.

In an aspect, hot stamping of the ultra-thin, laser responsive film and the thermoplastic black or opaque substrate may be carried out on the thermoplastic black or opaque substrate composition at a temperature of from about 100° C. to about 150° C., for a duration of from about one minute to about five minutes, and at a pressure of from about 5 bar to about 50 bar.

In one aspect, hot stamping of the ultra-thin, laser responsive film and the thermoplastic black or opaque substrate occurs by means of a tablet press machine. In an alternative aspect, hot stamping may occur by means of a plate vulcanization machine.

Formation of the film-substrate element must occur with particular attention to balancing an affinity of the ultra-thin, laser responsive film for the thermoplastic black or opaque substrate with an ability to be separate and detach from the black or opaque substrate after a laser structuring process. That is, adherence of the ultra-thin, laser responsive film with the thermoplastic black or opaque substrate facilitates laser structuring. Such cooperation within the film-substrate element allows for precision in conformance of the ultra-thin, laser responsive film to a designed specification of the thermoplastic black or opaque substrate. Thus, in an aspect, a comparison of a regular thermoplastic substrate alone and a regular thermoplastic substrate with an ultra-thin, laser responsive film attached by compression would exhibit no meaningful difference. Thus, in an aspect, the ultra-thin film thickness would bring about no compositional change to the substrate element. Accordingly, in certain aspects, the ultra-thin film element would not bring about any change to electrical, mechanical, or other physical or chemical properties of the substrate element. However, in an aspect, the ultra-thin film element would bring about a small change in appearance to the surface of the substrate element.

However, the ultra-thin film portion of the film-substrate element must maintain a removable property for post-laser structuring plating and the end-use of the thermoplastic substrate.

### Laser Processing

Aspects of the method for forming a laser-responsive article capable of metal plating further include, at step 130, applying a laser to the film-substrate element. Specifically, the method for forming a laser-responsive article capable of metal plating includes, at step 130, laser structuring the film-substrate element. During the laser structuring step 130, a laser is used to form a conductive path. In a still further aspect, the laser used to form the conductive path is laser direct structuring. In yet a further aspect, laser direct structuring comprises laser etching.

In an aspect, when the film-substrate element is exposed to the laser, elemental metal is released from the ultra-thin, laser responsive film portion of the film-substrate element. In a further aspect, the laser draws the circuit pattern onto the part and leaves behind a roughened surface containing embedded metal particles. In a yet further aspect, the embedded metal particles act as nuclei for the crystal growth during a subsequent plating process.

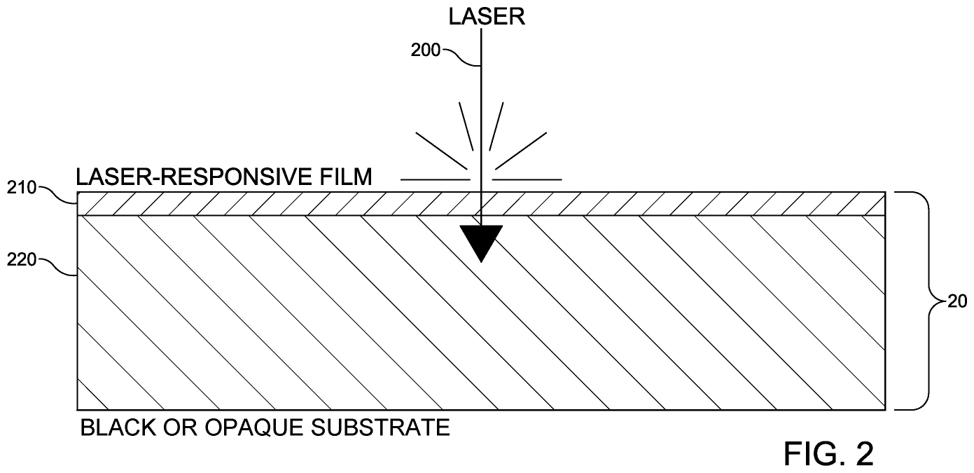

Referring now to FIG. 2, laser etching is carried out via a laser 200 to provide an activated ultra-thin, laser responsive film surface 210 which has been compressed with a thermoplastic black or opaque substrate composition 220 to form a film-substrate element 20.

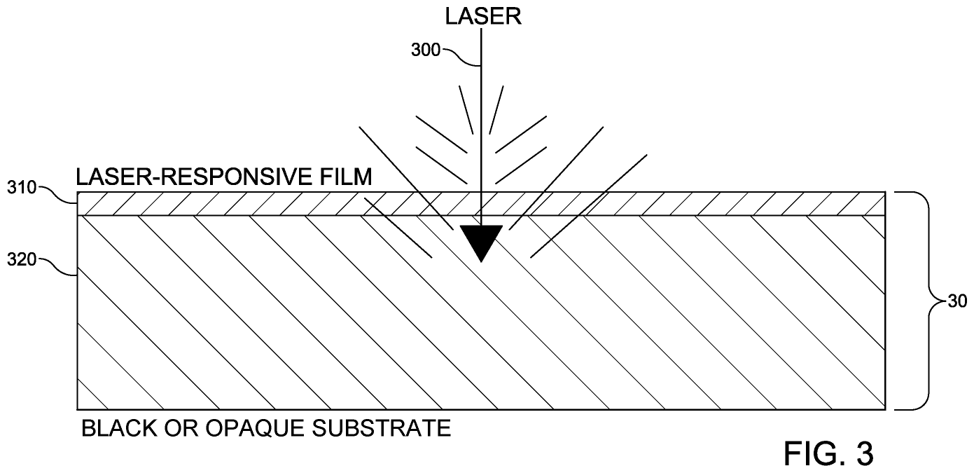

Referring now to FIG. 3, laser etching carried out via a laser 300 activates both the ultra-thin, laser responsive film 310 and the thermoplastic black or opaque substrate portion 320 of the film-substrate element 30.

In an aspect, the laser etching occurs by penetrating through the ultra-thin, laser responsive film portion of the film-substrate element to the underlying thermoplastic black or opaque substrate portion of the film-substrate element. Accordingly, the ultra-thin film portion of the film-substrate element may in some aspects appear with a hollow shape showing a track in the desired location on the surface of the film. As the laser will have penetrated the ultra-thin film portion of the film-substrate element, the shape of the track on the ultra-thin film portion will also appear as a conductive track on the surface of the thermoplastic black or opaque substrate element portion of the film-substrate element.

In a further aspect, the employed laser activatable, or laser responsive, catalyst within the ultra-thin, laser responsive film portion of the film-substrate element can release at least one metallic nucleus. In an even further aspect, the at least one metallic nucleus that has been released can act as a catalyst for a reductive copper plating process. In a still further aspect, the laser etching penetrates the film-substrate element at a depth of greater than about 5 μm to a depth of greater than about 15 μm. In a further aspect, at least one laser beam draws at least one pattern on the surface of the film-substrate element during the laser structuring step.

Laser direct structuring can be carried out on an article comprising the disclosed film-substrate element and corresponding composition at a power setting from about 1 watt (W) to about 14 W, a frequency from about 30 kilohertz (kHz) to about 120 kHz, and a speed of about 1 meter per second (m/s) to about 5 m/s. In a further aspect, laser etching is carried out at about 1 W to about 10 W power with a frequency from about 30 kHz to about 110 kHz and a speed of about 1 m/s to about 5 m/s. In a still further aspect, laser etching is carried out at about 1 w to about 10 w power with a frequency from about 40 kHz to about 100 kHz and a speed of about 2 m/s to about 4 m/s. In a yet further aspect, laser etching is carried out at about 3.5 W power with a frequency of about 40 kHz and a speed of about 2 m/s.

In various aspects, laser direct structuring is carried out on an article comprising the disclosed film-substrate element and corresponding composition at a power setting of about 2 W. In further aspects, laser direct structuring is carried out on an article comprising the disclosed blended thermoplastic compositions at a power setting of about 3 W, or at a power setting of about 4 W, or at a power setting of about 5 W, or at a power setting of about 6 W, or at a power setting of about 7 W, or at a power setting of about 8 W, or at a power setting of about 9 W, or at a power setting of about 10 W, or at a power setting of about 10 W.

In various aspects, laser direct structuring is carried out on an article comprising the disclosed comprising the disclosed film-substrate element and corresponding composition at a frequency setting of about 40 kHz. In further aspects, laser direct structuring is carried out on an article comprising the disclosed comprising the disclosed film-substrate element and corresponding composition at a frequency setting of about 50 kHz or at a frequency setting of about 60 kHz, or at a frequency setting of about 70 kHz, or at a frequency setting of about 80 kHz, or at a frequency setting of about 90 kHz, or at a frequency setting of about 100 kHz, or at a frequency setting of about 110 kHz, or at a frequency setting of about 120 kHz.

In various aspects, laser direct structuring is carried out on an article comprising the disclosed comprising the disclosed film-substrate element and corresponding composition at a speed of about 1 m/s. In further aspects, laser direct structuring is carried out on an article comprising the disclosed comprising the disclosed film-substrate element and corresponding composition at a speed of about 2 m/s, or at a speed of about 3 m/s, or at a speed of about 4 m/s, or at a speed of about 5 m/s.

As described above, in a further aspect, a rough surface can form in the LDS process. In a still further aspect, the rough surface can entangle a metal (e.g., copper) plate with a polymer matrix in the thermoplastic black or opaque substrate, which can provide adhesion between a metal plate and the thermoplastic black or opaque substrate. The metalizing step can, in various aspects, be performed using conventional techniques. Thus, in various aspects, plating a metal layer onto a conductive path is metallization. In a still further aspect, metallization can comprise the steps: a) cleaning the etched surface; b) additive build-up of tracks; and c) plating.

### Film Removal

Aspects of the method for forming a laser-responsive article capable of metal plating further include, at step 140, removing at least a portion of the film from the film-substrate element.

The film-substrate element balances an affinity of the film portion for the black or opaque substrate portion of the film-substrate element with an ability to be separated and detached from the black or opaque substrate portion after a laser structuring process. That is, the ultra-thin film portion of the film-substrate element must maintain a removable property for post-laser structuring metal plating and the end-use of the thermoplastic black or opaque substrate.

The step of removing at least a portion of the film from the film-substrate element may be performed through any one of various methods, including but not limited to manual peeling of at least a portion of the film from the film-substrate element. In a particular aspect, the step of removing at least a portion of the film from the film-substrate element is performed by the clasping of at least a portion of the film element and peeling so as to separate at least a portion of the film element from the black or opaque substrate element. In an alternative aspect, the step of removing at least a portion of the film from the film-substrate element may be performed through the use of a stretch machine capable of peeling the film element from the black or opaque substrate element. In certain aspects, the step of removing at least a portion of the film from the film-substrate element may be performed by a stretch machine capable of any further stretching method which may be performed in various environments including air and water. In a further aspect, separation of at least a portion of the film portion of the film-substrate element preserves the desired pattern, shape, and appearance of the black or opaque substrate for recovery and eventual end-use of the article.

In some aspects the step of removing at least a portion of the film from the film-substrate element (step 140) includes removing only a portion of the film from the film-substrate element. In other words, at least a portion of the film may remain on the black or opaque substrate in such aspects, and only the portion of the article in which the film remains will include a film-substrate element.

In other aspects the step of removing at least a portion of the film from the film-substrate element (step 140) includes removing the entire film from the film-substrate element. It will be recognized that in such aspects the article will no longer include a film-substrate element, only the black or opaque substrate.

### Metallization

Aspects of the method for forming a laser-responsive article capable of metal plating further include, at step 150, applying a metal plating to at least a portion of the black or opaque substrate. As described above, laser etching during the LDS process penetrates the film portion of the film-substrate element to reach the surface of the thermoplastic black or opaque substrate portion of the film-substrate element.

In an aspect, laser etching of the film-substrate element creates a rough surface of each of the film portion and the thermoplastic black or opaque substrate portion of the film-substrate element. Thus, in an aspect, removal of the film portion of the film-substrate element leaves a thermoplastic black or opaque substrate with a rough surface caused by laser etching. In a further aspect, the rough surface of each of the film portion and black or opaque substrate portion of the film-substrate element matches the pattern of the laser etching.

As described above, laser processing or structuring includes a method in which a laser draws a circuit pattern onto a part and leaves behind a roughened surface containing embedded metal particles.

In certain aspects, a substrate-film element would appear with a conductive track on the surface after laser processing. As described above, during laser processing, the body of the ultra-thin film portion of the film-substrate element is penetrated by the laser. Accordingly, the ultra-thin film portion of the film-substrate element may appear with a hollow shape showing a track in the desired location on the surface of the film. As the laser will have penetrated the ultra-thin film portion of the film-substrate element, the shape of the track on the ultra-thin film portion will also appear as a conductive track on the surface of the thermoplastic black or opaque substrate element portion of the film-substrate element.

However, in certain aspects, a black or opaque substrate element would have no visible difference in appearance when comparing before and after laser processing.

In a yet further aspect, the embedded metal particles act as nuclei for the crystal growth during a subsequent plating process. Thus, a comparison of a film-substrate element after plating and a regular thermoplastic black or opaque substrate surface following film removal would appear vastly different. For example, the film-substrate element would appear as it would before plating, with no meaningful patterns apparent to the eye. However, upon removal of the ultra-thin, laser responsive film, the thermoplastic black or opaque substrate surface would bear the resulting pattern of metal plating and would be visible to the naked eye.

In a still further aspect, the rough surface can entangle a metal (e.g., copper) plate with a polymer matrix in the thermoplastic black or opaque substrate, which can provide adhesion between a metal plate and the thermoplastic black or opaque substrate. The metalizing step can, in various aspects, be performed using conventional techniques. For example, in one aspect, an electro-less copper plating bath is used during the metallization step in the LDS process.

This described process of plating a metal layer onto a conductive path is one example of a metallization process. In a further aspect, the metallization step 150 can include the steps: a) cleaning the etched surface; b) additive build-up of tracks; and c) plating.

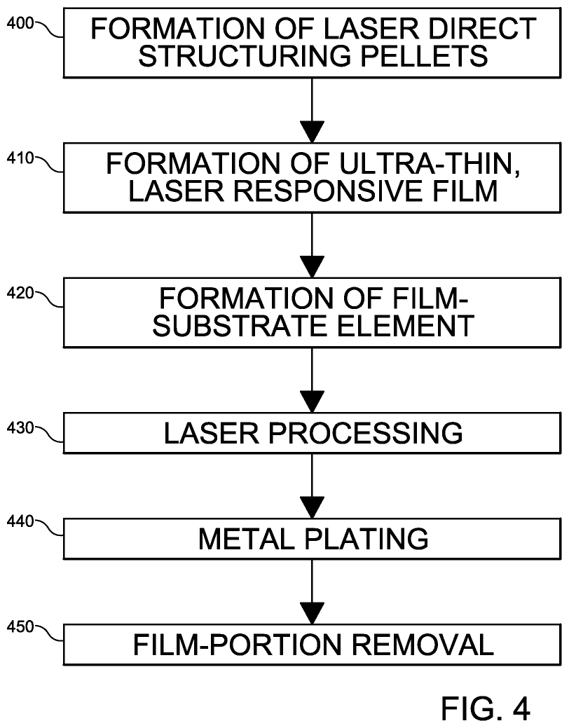

Referring now to FIG. 4, methods of the present disclosure and articles made therefrom include formation of laser direct structuring (LDS) pellets as shown in step 400. LDS pellets remain separate and are then selected to form a film.

Aspects of the method for forming a laser-responsive article capable of metal plating thus include, at step 410, forming an ultra-thin, laser responsive film from a laser-activatable material. The ultra-thin, laser responsive film formed from LDS pellets comprises a laser responsive catalyst to be used in a laser processing technique, such as LDS. After formation of the ultra-thin, laser responsive film, the film is compressed onto the surface of a thermoplastic black or opaque substrate.

Aspects of the method for forming a laser-responsive article capable of metal plating thus further include, at step 420, applying the film to a black or opaque substrate to form a film-substrate element utilizing a film pressing technology.

Following formation of the film-substrate element, aspects of the method for forming a laser-responsive article capable of metal plating further include, at step 430, applying a laser to the film-substrate element to form an etched film-substrate element.

Upon completion of step 430, aspects of the method for forming a laser-responsive article capable of metal plating further include, at step 440, applying a metal plating to at least a portion of the black or opaque substrate.

Finally, aspects of the method for forming a laser-responsive article capable of metal plating further include, at step 450, removing at least a portion of the etched and plated film-substrate element.

Thus, in an aspect, the ultra-thin, laser responsive film portion of the film-substrate element may be removed after a metal plating procedure leaving the thermoplastic black or opaque substrate with metal plating already completed.

Accordingly, in certain aspects, at least a portion of the ultra-thin, laser responsive film may be removed from the film-substrate element prior to metallization. However, in other aspects, at least a portion of the ultra-thin, laser responsive film may be removed from the film-substrate element after metallization.

### Methods of Manufacture

The compositions forming the articles of the present disclosure can be blended with the aforementioned ingredients by a variety of methods involving intimate admixing of the materials with any additional additives desired in the formulation. Such compositions may include blending of the LDS pellet, the thermoplastic black or opaque substrate composition, or both. Because of the availability of melt blending equipment in commercial polymer processing facilities, melt processing methods are generally preferred. Illustrative examples of equipment used in such melt processing methods include: co-rotating and counter-rotating extruders, single screw extruders, co-kneaders, disc-pack processors and various other types of extrusion equipment. The temperature of the melt in the present process is preferably minimized in order to avoid excessive degradation of the resins. It is often desirable to maintain the melt temperature between about 230° C. and about 350° C. in the molten resin composition, although higher temperatures can be used provided that the residence time of the resin in the processing equipment is kept short. In some embodiments the melt processed composition exits processing equipment such as an extruder through small exit holes in a die. The resulting strands of molten resin are cooled by passing the strands through a water bath. The cooled strands can be chopped into small pellets for packaging and further handling.

LDS pellets and/or thermoplastic black or opaque substrate compositions can be manufactured by various methods. For example, polymer, and/or other optional components are first blended, optionally with fillers in a HENSCHEL-Mixer® high speed mixer. Other low shear processes, including but not limited to hand mixing, can also accomplish this blending. The blend is then fed into the throat of a twin-screw extruder via a hopper. Alternatively, at least one of the components can be incorporated into the chosen composition by feeding directly into the extruder at the throat and/or downstream through a sidestuffer. Additives can also be compounded into a master batch with a desired polymeric resin and fed into the extruder. The extruder is generally operated at a temperature higher than that necessary to cause the composition to flow. The extrudate is immediately quenched in a water batch and pelletized. The pellets, so prepared, when cutting the extrudate can be one-fourth inch long or less as desired. Such pellets can be used for subsequent molding, shaping, or forming.

Specifically, in an aspect, such an extrudate as a pellet may be formed as an LDS pellet. In a further aspect, LDS pellets undergo extrusion to form an ultra-thin, laser responsive film. As described above, in an aspect, LDS pellets are subjected to a drying period at about 120° C. for approximately 4-6 hours. Following the drying period, LDS pellets are extruded at about 280° C. to form the ultra-thin, laser responsive film.

In a further aspect, the thermoplastic black or opaque substrate composition may be formed as a pellet. The thermoplastic black or opaque substrate composition may undergo extrusion to form a pellet. The thermoplastic pellets may undergo further injection molding to form a bulk thermoplastic black or opaque substrate on top of which the ultra-thin, laser responsive film may be compressed.

In another aspect, the thermoplastic pellets may undergo extrusion to form a thin, flexible, black or opaque substrate on top of which the ultra-thin, laser responsive film may be compressed. The final molded black or opaque substrate composition may be formed into any of various shapes.

### Articles of Manufacture

Articles formed according to the methods described herein may be shaped, formed, or molded by a variety of means such as injection molding, extrusion, rotational molding, blow molding and thermoforming to form articles such as, for example, personal computers, notebook and portable computers, cell phone antennas and other such communications equipment, medical applications, RFID applications, automotive applications, and the like.

The articles formed according to the methods described herein provide robust plating performance while maintaining good mechanical properties. Evaluation of the mechanical properties can be performed through various tests, such as Izod test, Charpy test, Gardner test, etc., according to several standards (e.g., ASTM D256). Unless specified to the contrary, all test standards described herein refer to the most recent standard in effect at the time of filing of this application.

In several aspects, the LDS compounds include a fixed loading amount of an LDS additive, such as copper chromium oxide, and varying amounts of thermoplastic base resins. In such aspects, fixed loading amounts of a stabilizer, an antioxidant, and a mold release agent were maintained in the LDS compounds.

In a further aspect, the molded article further comprises a conductive path formed by activation with a laser. In a yet further aspect, the article further comprises a metal layer plated onto the conductive path.

In various aspects, the articles formed according to the methods described herein may be used in the field of electronics. In a further aspect, non-limiting examples of fields which may use 3D MIDs, LDS process, or thermoplastic composition include electrical, electro-mechanical, Radio Frequency (RF) technology, telecommunication, automotive, aviation, medical, sensor, military, and security.

In one aspect, molded articles according to the present disclosure can be used to produce a device in one or more of the foregoing fields. Such devices which may use 3D MIDs, LDS processes, or thermoplastic compositions according to the present disclosure include, for example, computer devices, household appliances, decoration devices, electromagnetic interference devices, printed circuits, Wi-Fi devices, Bluetooth devices, GPS devices, cellular antenna devices, smart phone devices, automotive devices, military devices, aerospace devices, medical devices, such as hearing aids, sensor devices, security devices, shielding devices, RF antenna devices, or RFID devices.

As noted above, the disclosed articles formed according to the methods described herein are particularly well suited for use in the manufacture of electronic components and devices. As such, according to some aspects, the disclosed methods can be used to form articles such as printed circuit board carriers, burn in test sockets, flex brackets for hard disk drives, and the like.

### Definitions

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, reaction products, and the like.

Ranges can be expressed herein as from one value (first value) to another value (second value). When such a range is expressed, the range includes in some aspects one or both of the first value and the second value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the designated value, approximately the designated value, or about the same as the designated value. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

As used herein, the terms “optional” or “optionally” means that the subsequently described event or circumstance can or cannot occur, and that the description includes instances where said event or circumstance occurs and instances where it does not. For example, the phrase “optionally substituted alkyl” means that the alkyl group can or cannot be substituted and that the description includes both substituted and unsubstituted alkyl groups.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

References in the specification and concluding claims to parts by weight, of a particular element or component in a composition or article, denote the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

As used herein the terms “weight percent,” “wt %,” and “wt. %,” which can be used interchangeably, indicate the percent by weight of a given component based on the total weight of the composition, unless otherwise specified. That is, unless otherwise specified, all wt % values are based on the total weight of the composition. It should be understood that the sum of wt % values for all components in a disclosed composition or formulation are equal to 100.

The term “flowable” means capable of flowing or being flowed. Typically a polymer is heated such that it is in a melted state to become flowable.

° C. is degrees Celsius. μm is micrometer.

Izod Notched Impact tests are performed according to ISO 180-1A.

Each of the materials disclosed herein are either commercially available and/or the methods for the production thereof are known to those of skill in the art.

It is understood that the compositions disclosed herein have certain functions. Disclosed herein are certain structural requirements for performing the disclosed functions, and it is understood that there are a variety of structures that can perform the same function that are related to the disclosed structures, and that these structures will typically achieve the same result.

### Aspects

Aspect 1. An article formed from a process comprising, consisting of, or consisting essentially of:
(a) forming a film from a laser-activatable material, the film having a thickness of less than 100 μm;
(b) applying the film to a black or opaque substrate to form a film-substrate element;
(c) applying a laser to the film-substrate element;
(d) removing at least a portion of the film from the film-substrate element; and
(e) applying a metal plating to at least a portion of the black or opaque substrate, wherein step (d) may be performed prior to or after step (e).

Aspect 2. The article of Aspect 1, wherein the step of applying the film on the black or opaque substrate to form the film-substrate element comprises at least one of hot stamping or electrostatic absorption.

Aspect 3. The article of Aspect 2, wherein the film is applied to the black or opaque substrate by hot stamping at about 100° C. to about 150° C. for from about one minute to about five minutes at a pressure of from about 5 bar to about 50 bar.

Aspect 4. The article of Aspect 3, wherein the hot stamping is performed by one of a tablet press machine or a plate vulcanization machine.

Aspect 5. The article of any one of Aspects 1-4, wherein the laser-activatable material comprises a polymer.

Aspect 6. The article of any one of Aspects 1-5, wherein the laser-activatable material comprises polycarbonate.

Aspect 7. The article of any one of Aspects 1-6, wherein the film has a thickness of about 5 μm to about 15 μm.

Aspect 8. The article of any one of Aspects 1-7, wherein the step of forming a film from a laser-activatable material comprises extruding film from pellets.

Aspect 9. The article of any one of Aspects 1-8, wherein the article is one of a computer device, electromagnetic interference device, printed circuit, Wi-Fi device, Bluetooth device, GPS device, cellular antenna device, smart phone device, automotive device, medical device, sensor device, security device, shielding device, RF antenna device, LED device and RFID device.

Aspect 10. The article of any one of Aspects 1-9, wherein the article is a component of a cell phone antenna.

Aspect 11. The article of any one of Aspects 1-10, wherein the film has a thickness from about 1 μm to about 20 μm.

Aspect 12. The article of any one of Aspects 1-10, wherein the film has a thickness from about 1 μm to about 50 μm.

Aspect 13. The article of any one of Aspects 1-10, wherein the film has a thickness from about 1 μm to about 100 μm.

Aspect 14. A method comprising, consisting of, or consisting essentially of:
(a) forming a film from a laser-activatable material, the film having a thickness of less than 100 μm;
(b) applying the film to a black or opaque substrate to form a film-substrate element;
(c) applying a laser to the film-substrate element;
(d) removing at least a portion of the film from the film-substrate element; and
(e) applying a metal plating to at least a portion of the black or opaque substrate, wherein step (d) may be performed prior to or after step (e).

Aspect 15. The method of Aspect 14, wherein the step of applying the film to a black or opaque substrate to form the film-substrate element comprises at least one of hot stamping or electrostatic absorption.

Aspect 16. The method of any one of Aspects 14-15, wherein the film is applied to the black or opaque substrate by hot stamping at about 100° C. to about 150° C. for from about one minute to about five minutes at a pressure of from about 5 bar to about 50 bar.

Aspect 17. The method of Aspect 16, wherein the hot stamping is performed by one of a tablet press machine or a plate vulcanization machine.

Aspect 18. The method of any one of Aspects 14-17, wherein the material comprises a polymer.

Aspect 19. The method of any one of Aspects 14-18, wherein the material comprises polycarbonate.

Aspect 20. The method of any one of Aspects 14-19, wherein the film has a thickness of about 5 μm to about 15 μm.

Aspect 21. The method of any one of Aspects 14-19, wherein the film has a thickness from about 1 μm to about 20 μm.

Aspect 22. The article of any one of Aspects 14-19, wherein the film has a thickness from about 1 μm to about 50 μm.

Aspect 23. The article of any one of Aspects 14-19, wherein the film has a thickness from about 1 μm to about 100 μm.

Aspect 24. The method of any one of Aspects 14-23, wherein the article is one of a computer device, electromagnetic interference device, printed circuit, Wi-Fi device, Bluetooth device, GPS device, cellular antenna device, smart phone device, automotive device, medical device, sensor device, security device, shielding device, RF antenna device, LED device and RFID device.

Aspect 25. The method of any one of Aspects 14-24, wherein the article is a component of a cell phone antenna.

Aspect 26. A method comprising, consisting of, or consisting essentially of:
(a) forming a film from a laser-activatable material, the film having a thickness of less than 100 μm;
(b) applying the film to a black or opaque substrate to form a film-substrate element;
(c) applying a laser to the film-substrate element;
(d) applying a metal plating to at least a portion of the film-substrate element; and
(e) removing at least a portion of the film from the film-substrate element,
wherein step (d) may be performed prior to or after step (e).

### Examples

Polycarbonate (PC)-based LDS pellets were dried at 120° C. for 4-6 hours and the film was extruded at about 280° C. to achieve a transparent or translucent film with the film thickness of from about 5 μm to about 15 μm.

As an illustrative example, a PC-based LDS film (5-15 μm thickness) was cut to the appropriate size according to the PC substrate shape and size. A hot stamping method was implemented at 100-150° C. via a hot stamping machine (such as tablet press machine or plate vulcanization machine) for 1-5 minutes at a pressure from 5-50 bar a black substrate to achieve a laminate structure. The film adhered to the black substrate and no obvious detached effects from the black substrate were observed.

1. An article formed from a process comprising:
(a) forming a film from a laser-activatable material, the film having a thickness of less than 100 μm;
(b) applying the film to a black or opaque substrate to form a film-substrate element;
(c) applying a laser to the film-substrate element;
(d) removing at least a portion of the film from the film-substrate element; and
(e) applying a metal plating to at least a portion of the black or opaque substrate, wherein step (d) may be performed prior to or after step (e).

2. The article of claim 1, wherein the step of applying the film on the black or opaque substrate to form the film-substrate element comprises at least one of hot stamping or electrostatic absorption.

3. The article of claim 2, wherein the film is applied to the black or opaque substrate by hot stamping at about 100° C. to about 150° C. for from about one minute to about five minutes at a pressure of from about 5 bar to about 50 bar.

4. The article of claim 3, wherein the hot stamping is performed by one of a tablet press machine or a plate vulcanization machine.

5. The article of claim 1, wherein the laser-activatable material comprises a polymer.

6. The article of claim 1, wherein the laser-activatable material comprises polycarbonate.

7. The article of claim 1, wherein the film has a thickness of about 5 μm to about 15 μm.

8. The article of claim 1, wherein the step of forming a film from a laser-activatable material comprises extruding film from pellets.

9. The article of claim 1, wherein the article is one of a computer device, electromagnetic interference device, printed circuit, Wi-Fi device, Bluetooth device, GPS device, cellular antenna device, smart phone device, automotive device, medical device, sensor device, security device, shielding device, RF antenna device, LED device and RFID device.

10. The article of claim 1, wherein the article is a component of a cell phone antenna.

11. A method comprising:
(a) forming a film from a laser-activatable material, the film having a thickness of less than 100 μm;
(b) applying the film to a black or opaque substrate to form a film-substrate element;
(c) applying a laser to the film-substrate element;
(d) removing at least a portion of the film from the film-substrate element; and
(e) applying a metal plating to at least a portion of the black or opaque substrate, wherein step (d) may be performed prior to or after step (e).

12. The method of claim 11, wherein the step of applying the film to a black or opaque substrate to form the film-substrate element comprises at least one of hot stamping or electrostatic absorption.

13. The method of claim 11, wherein the film is applied to the black or opaque substrate by hot stamping at about 100° C. to about 150° C. for from about one minute to about five minutes at a pressure of from about 5 bar to about 50 bar.

14. The method of claim 13, wherein the hot stamping is performed by one of a tablet press machine or a plate vulcanization machine.

15. The method of claim 11, wherein the material comprises a polymer.

16. The method of claim 11, wherein the material comprises polycarbonate.

17. The method of claim 11, wherein the film has a thickness of about 5 μm to about 15 μm.

18. The method of claim 11, wherein the article is one of a computer device, electromagnetic interference device, printed circuit, Wi-Fi device, Bluetooth device, GPS device, cellular antenna device, smart phone device, automotive device, medical device, sensor device, security device, shielding device, RF antenna device, LED device and RFID device.

19. The method of claim 11, wherein the article is a component of a cell phone antenna.

20. A method comprising:
(a) forming a film from a laser-activatable material, the film having a thickness of less than 100 μm;
(b) applying the film to a black or opaque substrate to form a film-substrate element;
(c) applying a laser to the film-substrate element;
(d) applying a metal plating to at least a portion of the film-substrate element; and
(e) removing at least a portion of the film from the film-substrate element, wherein step (d) may be performed prior to or after step (e).
